(19) United States
(12) Patent Application Publication
(10) Pub. No.: US 2004/0157410 A1
(43) Pub. Date: Aug. 12, 2004

(54) Semiconductor device, semiconductor module, electronic equipment, method for manufacturing semiconductor device, and method for manufacturing semiconductor module

(75) Inventor: Koji Yamaguchi, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/753,360

(22) Filed: Jan. 9, 2004

(30) Foreign Application Priority Data
Jan. 16, 2003 (JP) 2003-007770

(51) Int. Cl. H01L 21/301

(52) U.S. Cl. 438/460

(57) ABSTRACT

To suppress enlargement of the chip size, and improve the reliability in interlayer connections. Grooves 4a-4c are provided at positions of scribe lines SL of semiconductor substrates 1a-1c; and conductive material 11 is filled in the grooves 4a-4c provided in sections of the semiconductor substrates 1a-1c after the semiconductor substrates 1a-1c are stacked in layers.

### BACKGROUND OF THE INVENTION

1. Field of Invention

The present invention relates to semiconductor devices, semiconductor modules, electronic equipment, methods of manufacturing semiconductor devices, and methods of manufacturing semiconductor modules. In particular, the invention relates to methods of providing interlayer connections in stacked layered structures of semiconductor chips.

2. Description of Related Art

A related art method of providing a stacked layered structure of semiconductor chips in semiconductor devices includes a method in which dry etching is used to form through holes in a semiconductor substrate, and interlayer connections among semiconductor substrates are provided via through electrodes embedded in the through holes.

FIGS. 14(a)-15(d) are cross-sectional views showing a related art method of manufacturing a semiconductor module.

Referring to FIG. 14(a), pad electrodes 102 are formed on an active surface 101′ of a semiconductor substrate 101. Then, for example, a photolithography technique and a dry etching technique are used to form trench sections 103 in the semiconductor substrate 101 through the pad electrodes 102.

The thickness T11 of the semiconductor substrates 101 can be 625 μm when a 6-inch wafer is used, and 725 μm when an 8-inch wafer is used. The depth D2 of the trench section 103 can be, for example, 70 μm.

Next, as indicated in FIG. 14(b), for example, a photolithography technique and CVD technique are used to form dielectric films on bottom surfaces and side surfaces of the trench sections 103. A silicon oxide film or a silicon nitride film may be used as the dielectric film 104, for example.

Next, as indicated in FIG. 14(c), seed electrodes 105 are formed on the semiconductor substrate 101 including inside the trench sections 103 by, for example, sputtering or vapor deposition. As the seed electrodes 105, conductive material, such as, for example, nickel (Ni), chrome (Cr), titanium (Ti), or tungsten (W) can be used.

Then, a plating resist layer 106 provided with opening sections 106′ at locations corresponding to the trench sections 103 is formed on the semiconductor substrate 101 having the seed electrodes 105 formed thereon.

Then, by conducting electrolytic plating using the seed electrodes 105 as plating terminals, embedded electrodes 107 within the trench sections 103 are formed through the opening sections 106′ that are provided in the plating resist layer 106.

The embedded electrodes 107 can be formed in a manner to bulge out of the trench sections 103 such that not only the trench sections 103 but also the opening sections 106′ are embedded with them. Accordingly, the embedded electrodes 107 can protrude over the semiconductor substrates 101, such that interlayer connections as indicated in FIG. 15(d) can be stably provided.

For example, nickel (Ni), copper (Cu), gold (Au) or the like can be used for the embedded electrodes 107.

Next, as indicated in FIG. 14(d), the plating resist layer 106 is removed, and the seed electrodes 106 are etched using the embedded electrodes 107 as masks to thereby expose the active surface 101′ of the semiconductor wafer W.

Next, as indicated in FIG. 15(a), the back surface 101″ of the semiconductor substrate 101 is grounded by using back grinding to thin down the semiconductor substrate 101.

The back grinding of the back surface 101″ of the semiconductor substrate 101 is finished before the dielectric film 104 is exposed so that the thickness T12 of the semiconductor substrate 101 after the back grinding is, for example, 100 μm.

As indicated in FIG. 15(b), the back surface 101″ of the semiconductor substrate 101 is dry-etched to further thin down the semiconductor substrate 101 such that the trench sections 103 penetrate the semiconductor substrate 101 to form through holes 103′ therein, and expose tip portions of the embedded electrodes 107 covered with the dielectric films 104 to form through electrodes 107′. The thickness T13 of the semiconductor substrate 101 after the dry etching can be, for example, 50 μm. Also, as etching gas for the dry etching of the back surface 101″ of the semiconductor substrate 101, for example, Cl₂, HBr or SF₆ can be used.

Next, as indicated in FIG. 15(c), by dry etching the dielectric films 104 at the tips of the through electrodes 107′, the dielectric films 104 at the tips of the through electrodes 107′ are removed. As etching gas for the dry etching of the dielectric films 104 at the tips of the through electrodes 107′, for example, Cl₂, HBr or SF₆ can be used.

Next, as indicated in FIG. 15(d), the semiconductor substrates 101a-101c are stacked in layers such that the through electrodes 107a-107c formed on the respective semiconductor substrates 101a-101c are in contact with one another. Resin 108a and 108b is filled in gaps among the semiconductor substrates 101a-101c to form a stacked layered structure of the semiconductor substrates 101a-101c.

### SUMMARY OF THE INVENTION

However, according to the related art method of manufacturing a semiconductor module, the through electrodes 107a-107c are formed within the semiconductor substrates 101a-101c, such that the through electrodes 107a-107c in upper and lower layers need to be aligned with one another in order to provide interlayer connections.

For this reason, in the related art semiconductor module, the diameter of the through electrodes 107a-107c need to be enlarged to facilitate the alignment of the through electrodes 107a-107c in upper and lower layers, which is problematical because the chip size becomes larger by the amount enlarged.

Also, in the related art semiconductor module, the through electrodes 107a-107c in upper and lower layers need to be connected to one another in order to provide interlayer connections.

For this reason, when the chip size is larger, due to warps in the semiconductor substrates 101a-101c and height variations among the through electrodes 107a-107c, there are problems in that connections among the through electrodes 107a-107c in upper and lower layers become insufficient, and the reliability in the interlayer connections are deteriorated.

Accordingly, the present invention provides semiconductor devices, semiconductor modules, electronic equipment, methods of manufacturing semiconductor devices, and methods of manufacturing semiconductor modules, which can control enlargement of the chip size, and enhance the reliability in interlayer connections.

To address or solve the above, a semiconductor device of aspect 1 includes: a wiring layer formed on a main surface of a semiconductor chip; and conductive layers for interlayer connections that are connected to the wiring layer and formed in a side wall of the semiconductor chip.

As a result, interlayer connections among semiconductor chips can be provided without providing through electrodes in active regions of the semiconductor chips.

For this reason, while reducing or suppressing enlargement of the chip size, conductive layers to provide interlayer connections can be readily expanded, and conductive layers for interlayer connections can be formed after the semiconductor chips are stacked in layers.

As a result, the conductive layers for interlayer connections in upper and lower layers can be readily aligned, and when conductive layers for interlayer connections are connected, the influence of warps in semiconductor substrates and height variations among the conductive layers for interlayer connections can be reduced or eliminated, and the reliability in the interlayer connections can be enhanced.

Also, a semiconductor device of aspect 2 includes: electrode pads formed on a main surface of a semiconductor chip; grooves formed in a section of the semiconductor chip that traverses in a thickness direction of the semiconductor chip; conductive layers filled in the grooves; and wiring layers that connect the electrode pads and the conductive layers.

Accordingly, by flowing conductive material along the side walls of the semiconductor chips, the side walls of the semiconductor chips can be filled with conductive layers; and conductive layers to provide interlayer connections can be formed after the semiconductor chips are stacked in layers, and through electrodes do not need to be provided in active regions of the semiconductor chips.

For this reason, the conductive layers in upper and lower layers can be readily aligned with one another; and when conductive layers in upper and lower layers are connected to one another, the influence of height variations among the conductive layers and warps in the semiconductor chips can be reduced or eliminated, and the reliability in the interlayer connections can be enhanced.

Further, a semiconductor module of aspect 3 includes: semiconductor chips stacked in layers; conductive layers that are formed in side walls of the respective semiconductor chips to provide interlayer connections among the semiconductor chips; and wiring layers that are formed on main surfaces of the respective semiconductor chips and connected to the conductive layers.

Accordingly, interlayer connections can be provided through side walls of the semiconductor chips, and through electrodes do not need to be provided in active surfaces.

For this reason, while reducing or suppressing enlargement of the chip size, the alignment for interlayer connections is facilitated, and the connection reliability can be enhanced.

Also, a semiconductor module of aspect 4 includes: semiconductor chips stacked in layers; electrode pads formed on main surfaces of the respective semiconductor chips; grooves that are formed in sections of the respective semiconductor chips that traverse in a thickness direction of the semiconductor chips; conductive layers filled in the grooves to provide interlayer connections among the semiconductor chips; and wiring layers that connect the electrode pads and the conductive layers, respectively.

Accordingly, by flowing conductive material along the side walls of the semiconductor chips stacked in layers, interlayer connections among the semiconductor chips can be provided; and when the semiconductor chips are stacked in layers, there is no need to connect through electrodes in upper and lower layers.

For this reason, the semiconductor chips can be readily aligned with one another, and the influence of height variations among the conductive layers and warps in the semiconductor chips can be reduced or eliminated, and the reliability in the interlayer connections can be enhanced.

Also, a semiconductor module of aspect 5 includes: semiconductor chips stacked in layers; electrode pads formed on main surfaces of the respective semiconductor chips; grooves that are formed in sections of the respective semiconductor chips that traverse in a thickness direction of the semiconductor chips; wiring layers that connect the electrode pads and the conductive layers; pin-like terminals that are embedded in the grooves and disposed in a stacking direction of the semiconductor chips; an interposer substrate with the pin-like terminals standing thereon; and conductive layers filled in the grooves with the pin-like terminals therein.

Accordingly, by stacking the semiconductor chips in layers on the interposer substrate along the pin-like terminals, the semiconductor chips can be aligned with one another, and solder material can be readily attached along the pin-like terminals.

For this reason, conductive layers can be readily filled along the grooves formed in the sections by solder dip or the like, such that a three-dimensional mounting of the semiconductor chips can be readily realized.

Also, a semiconductor module of aspect 6 is provided such that the semiconductor chips are stacked in layers through dielectric resin.

Accordingly, by coating dielectric resin all over the semiconductor chips, interlayer connections can be made and the semiconductor chips can be insulated from one another.

As a result, without complicating the manufacturing process, insulation among the semiconductor chips can be secured, the sealing property of the semiconductor chips can be readily enhanced, and the reliability of the semiconductor module can be enhanced.

Also, a semiconductor module of aspect 7 includes: an interposer substrate having a wiring layer formed on a main surface thereof; a semiconductor chip that is connected to the wiring layer and mounted on the interposer substrate; grooves formed in a side wall of the interposer substrate that traverses in a thickness direction of the interposer substrate; and conductive layers filled in the grooves.

Accordingly, even when semiconductor chips are mounted on an interposer substrate, interlayer connections among the semiconductor chips can be provided through the side walls of the interposer substrate; and a three-dimensional mounting of the semiconductor chips can be readily realized and the reliability in interlayer connections can be enhanced even when the types and/or chip sizes of the semiconductor chips are different from one another.

Also, a semiconductor module of aspect 8 includes: interposer substrates stacked in layers; wiring layers formed on main surfaces of the interposer substrates; semiconductor chips that are connected to the wiring layers and mounted on the interposer substrates; grooves formed in side walls of the interposer substrates that traverse in a thickness direction of the interposer substrates; conductive layers filled in the grooves to provide interlayer connections among the interposer substrates; and recessed sections formed in back surfaces of the interposer substrates to store the semiconductor chips.

As a result, even when the semiconductor chips are mounted on the interposer substrates, the influence of protrusions of the semiconductor chips can be reduced or avoided, and interlayer connections among the semiconductor chips can be provided through the side walls of the interposer substrates.

For this reason, even when the types and/or chip sizes of the semiconductor chips are different from one another, a three-dimensional mounting of the semiconductor chips can be readily realized, and interlayer connections can be realized while the influence of warps in the interposer substrates and height variations among the through electrodes can be reduced or eliminated, and the reliability in the interlayer connections can be enhanced.

Also, a semiconductor module of aspect 9 includes: an intermediate substrate having an opening section formed therein; interposer substrates stacked in layers through the intermediate substrate; wiring layers formed on main surfaces of the interposer substrates; semiconductor chips that are connected to the wiring layers and mounted on the interposer substrates; first grooves formed in side walls of the interposer substrates that traverse in a thickness direction of the interposer substrates; second grooves formed in a side wall of the intermediate substrate that traverses in a thickness direction of the intermediate substrate; and conductive layers filled in the first grooves and the second grooves to provide interlayer connections among the interposer substrates through the intermediate substrate.

Accordingly, even when the semiconductor chips are mounted on plane interposer substrates, the influence of protrusions of the semiconductor chips can be reduced or avoided, and interlayer connections among the semiconductor chips can be provided through the side walls of the interposer substrates.

For this reason, even when the types and/or chip sizes of the semiconductor chips are different from one another, a three-dimensional mounting of the semiconductor chips can be readily realized, and interlayer connections can be realized without complicating the structure of the interposer substrates, and the reliability in the interlayer connections can be enhanced.

Further, an electronic device of aspect 10 includes: semiconductor chips stacked in layers; electrode pads formed on main surfaces of the respective semiconductor chips; grooves that are formed in sections of the respective semiconductor chips that traverse in a thickness direction of the semiconductor chips; conductive layers filled in the grooves to provide interlayer connections among the semiconductor chips; wiring layers that connect the electrode pads and the conductive layers, respectively; and an electronic component that is connected to the semiconductor chips through the conductive layers.

As a result, by flowing conductive material along the side walls of the semiconductor chips stacked in layers, interlayer connections among the semiconductor chips can be provided; and the semiconductor chips can be readily aligned with one another while reducing or suppressing enlargement of the chip size, and the influence of height variations among the conductive layers and warps in the semiconductor chips can be reduced or eliminated.

For this reason, the electronic device can be made smaller and lighter, and the reliability of the electronic device can be enhanced.

Also, an electronic device of aspect 11 includes: semiconductor chips stacked in layers; electrode pads formed on main surfaces of the respective semiconductor chips; grooves that are formed in sections of the respective semiconductor chips that traverse in a thickness direction of the semiconductor chips; wiring layers that connect the electrode pads and the conductive layers, respectively; pin-like terminals that are inserted in the grooves and disposed in a stacking direction of the semiconductor chips; an interposer substrate with the pin-like terminals standing thereon; conductive layers filled in the grooves with the pin-like terminals therein; and an electronic component that is connected to the semiconductor chips through the conductive layers.

As a result, the semiconductor chips can be precisely stacked in layers, and conductive layers can be readily filled along the grooves formed in the sections thereof, enlargement in the chip size can be reduced or suppressed, and a three-dimensional mounting of the semiconductor chips can be readily realized.

For this reason, the electronic device can be made smaller and lighter, and the reliability of the electronic device can be enhanced.

Further, an electronic device of aspect 12 includes: interposer substrates stacked in layers; wiring layers formed on main surfaces of the interposer substrates; semiconductor chips that are connected to the wiring layers and mounted on the interposer substrates; grooves formed in side walls of the interposer substrates that traverse in a thickness direction of the interposer substrates; conductive layers filled in the grooves for providing interlayer connections among the interposer substrates; recessed sections formed in back surfaces of the interposer substrates to store the semiconductor chips; and an electronic component that is connected to the semiconductor chips through the conductive layers.

Accordingly, even when the types and/or chip sizes of the semiconductor chips are different from one another, a three-dimensional mounting of the semiconductor chips can be readily realized while reducing or suppressing enlargement of the chip size, and the reliability in the interlayer connections can be enhanced.

For this reason, the electronic device can be made smaller in size and lighter, and the reliability in the electronic device can be enhanced. Also, a variety of functions can be readily added to the electronic device.

Further, an electronic device of aspect 13 includes: an intermediate substrate having an opening section formed therein; interposer substrates stacked in layers through the intermediate substrate; wiring layers formed on main surfaces of the interposer substrates; semiconductor chips that are connected to the wiring layers and mounted on the interposer substrates; first grooves formed in side walls of the interposer substrates that traverse in a thickness direction of the interposer substrates; second grooves formed in a side wall of the intermediate substrate that traverses in a thickness direction of the intermediate substrate; conductive layers filled in the first grooves and the second grooves to provide interlayer connections among the interposer substrates through the intermediate substrate; and an electronic component that is connected to the semiconductor chips through the conductive layers.

Accordingly, even when the types and/or chip sizes of the semiconductor chips are different from one another, a three-dimensional mounting of the semiconductor chips can be readily realized while reducing or suppressing enlargement of the chip size, and the reliability in the interlayer connections can be enhanced while preventing the interposer substrates from becoming complicated.

For this reason, the electronic device can be made smaller in size and lighter, and the reliability in the electronic device can be enhanced. Also, a variety of functions can be readily added to the electronic device while reducing or suppressing an increase in the cost.

Also, a method of manufacturing a semiconductor device of aspect 14 includes: forming through holes on cutting lines of a semiconductor wafer; cutting the semiconductor wafer along the cutting lines into chips; and filling conductive layers in the through holes divided by the cutting.

Accordingly, by conducting processings on the plane surface of the semiconductor wafer, grooves can be formed in side walls of the semiconductor wafer, and conductive layers can be readily filled in sections of the semiconductor wafer without directly processing the sections of the semiconductor wafer.

For this reason, conductive layers can be provided on the side walls of the semiconductor chip without complicating the manufacturing process, and the conductive layers in upper and lower layers can be readily aligned with one another. Moreover, when the conductive layers in upper and lower layers are to be connected, the influence of height variations of the conduction layers and/or warps in the semiconductor chips can be eliminated, such that the reliability in interlayer connections can be reduced or enhanced while reducing or preventing the throughput from lowering.

Further, a method of manufacturing a semiconductor device of aspect 15 includes: forming trench sections on cutting lines of a semiconductor wafer having wiring layers formed thereon; forming dielectric films within the trench sections; forming an under barrier metal layer that covers the dielectric films and is connected to the wiring layers; thinning a back surface of the semiconductor wafer to thereby make the trench sections penetrate to form through holes along the cutting lines; cutting the semiconductor wafer along the cutting lines into chips; and filling conductive layers in the through holes that are divided by the cutting step.

Accordingly, by cutting a semiconductor wafer having through holes formed therein, grooves can be formed in side walls of the semiconductor wafer; and conductive layers can be readily filled in sections of the semiconductor wafer without directly processing the sections of the semiconductor wafer, and interlayer connections can be provided by effectively using marginal regions that are required to cut the semiconductor wafer.

For this reason, the conductive layers can be provided on the side walls of the semiconductor chips without complicating the manufacturing process, and there is no need to form through electrodes by sacrificing the active regions.

Consequently, the conductive layers in upper and lower layers can be readily aligned with one another while reducing or suppressing enlargement of the chip size; the influence of height variations among the conductive layers and warps in the semiconductor chips can be reduced or eliminated when the conductive layers in upper and lower layers are connected to one another; and the reliability in interlayer connections can be enhanced while checking the throughput from lowering.

Also, a method of manufacturing a semiconductor module of aspect 16 includes: forming conductive layers on side walls of a semiconductor chip; and a step of providing interlayer connections through the conductive layers formed on the side walls of the semiconductor chip.

Accordingly, interlayer connections among semiconductor chips can be provided without providing through electrodes in active regions of the semiconductor chips; the conductive layers in upper and lower layers can be readily aligned with one another; the influence of height variations among the conductive layers and warps in the semiconductor chips can be reduced or eliminated; and the reliability in interlayer connections can be enhanced.

Also, a method of manufacturing a semiconductor module of aspect 17 includes: forming through holes on cutting lines of a semiconductor wafer; cutting the semiconductor wafer along the cutting lines into chips; stacking the semiconductor chips formed by the cutting step; and filling conductive layers in the through holes cut by the cutting.

Accordingly, by cutting a semiconductor wafer having through holes formed therein, grooves can be formed in side walls of the semiconductor wafer; and by flowing conductive material along the side walls of the semiconductor chips stacked in layers, interlayer connections among the semiconductor chips can be provided.

For this reason, when the semiconductor chips are stacked in layers, there is no need to connect through electrodes in upper and lower layers such that the semiconductor chips can be readily aligned with one another; and the influence of height variations among the conductive layers and warps in the semiconductor chips can be reduced or eliminated such that the reliability in interlayer connections can be enhanced.

Also, a method of manufacturing a semiconductor module of aspect 18 includes: forming through electrodes on cutting lines of a semiconductor wafer; cutting the semiconductor wafer along the cutting lines into chips; and providing interlayer connections among the semiconductor chips formed by the cutting step via the through electrodes that are cut by the cutting.

Consequently, by cutting the semiconductor wafer having through electrodes formed therein, conductive layers can be collectively formed in side walls of the semiconductor wafer.

For this reason, the conductive layers can be accurately formed in sections of the semiconductor wafer while omitting the filling of conductive material after cutting the semiconductor wafer, and interlayer connections can be provide through effectively using marginal regions necessary to cut the semiconductor wafer.

Further, a method of manufacturing a semiconductor module of aspect 19 includes: forming trench sections on cutting lines of a semiconductor wafer having wiring layers formed thereon; forming dielectric films within the trench sections; forming an under barrier metal layer that covers the dielectric films and is connected to the wiring layers; thinning a back surface of the semiconductor wafer to thereby make the trench sections penetrate to form through holes along the cutting lines; cutting the semiconductor wafer along the cutting lines into chips; stacking the semiconductor chips formed by the cutting step; and filling conductive layers in the through holes that are divided by the cutting step.

Accordingly, by cutting a semiconductor wafer having through holes formed therein, grooves can be formed in side walls of the semiconductor wafer; and by flowing conductive material along the side walls of the semiconductor chips stacked in layers, interlayer connections among the semiconductor chips can be provided.

For this reason, the conductive layers can be provided in the side walls of the semiconductor chips without complicating the manufacturing process, and there is no need to form through electrodes through sacrificing the active regions.

As a result, the conductive layers in upper and lower layers can be readily aligned with one another while reducing or suppressing enlargement of the chip size; the influence of height variations among the conductive layers and warps in the semiconductor chips can be reduced or eliminated when the conductive layers in upper and lower layers are connected to one another; and the reliability in interlayer connections can be enhanced while checking the throughput from lowering.

Also, a method of manufacturing a semiconductor module of aspect 20 includes: forming through holes on cutting lines of a semiconductor wafer; cutting the semiconductor wafer along the cutting lines into chips; stacking the semiconductor chips on a interposer substrate having pin-like terminals standing thereon in a manner that the pin-like terminals are inserted in the through holes divided by the cutting; and filling conductive layers in the through holes that are cut.

Accordingly, by stacking the semiconductor chips on the interposer substrates along the pin-like terminals, the semiconductor chips can be aligned with one another, and solder material or the like can be readily attached along the pin-like terminals, such that a three-dimensional mounting of the semiconductor chips can be readily realized.

Further, a method of manufacturing a semiconductor module of aspect 21 includes: mounting semiconductor chips on interposer substrates having grooves formed in side walls thereof and recessed sections formed in back surfaces thereof; stacking the interposer substrates having the semiconductor chips mounted thereon in layers such that each of the semiconductor chips is stored in each of the recessed sections of an upper layer of the stacked interposer substrates; and filling conductive layers in the grooves of the interposer substrates to provide interlayer connections.

Accordingly, even when the types and/or chip sizes of the semiconductor chips are different from one another, a three-dimensional mounting of the semiconductor chips can be readily realized; and interlayer connections can be realized while reducing or eliminating the influence of height variations among the through electrodes and warps in the interposer substrates, and the reliability in the interlayer connections can be enhanced.

Also, a method of manufacturing a semiconductor module of aspect 22 includes: mounting semiconductor chips on interposer substrates having grooves formed in side surfaces thereof; stacking the interposer substrates having the semiconductor chips mounted thereon through intermediate substrates having opening sections formed in main surfaces thereof and grooves formed in side walls thereof; and filling conductive layers in the grooves of the interposer substrates and the intermediate substrates to provide interlayer connections.

Accordingly, even when the types and/or chip sizes of the semiconductor chips are different from one another, a three-dimensional mounting of the semiconductor chips can be readily realized, and interlayer connections can be realized without complicating the structure of the interposer substrates, and the reliability in the interlayer connections can be enhanced.

### BRIEF DESCRIPTION OF THE DRAWINGS

FIGS. 1(a)-1(d) are cross-sectional views showing a method of manufacturing a semiconductor module in accordance with a first exemplary embodiment of the present invention;

FIGS. 2(a) and 2(b) are cross-sectional views showing the method of manufacturing a semiconductor module in accordance with the first exemplary embodiment of the present invention;

FIGS. 3(a) and 3(b) are perspective views showing the method of manufacturing a semiconductor module in accordance with the first exemplary embodiment of the present invention;

FIGS. 4(a) and 4(b) are perspective views showing the method of manufacturing a semiconductor module in accordance with the first exemplary embodiment of the present invention;

FIGS. 5(a) and 5(b) are side views showing a method of filling conductive material in accordance with an exemplary embodiment of the present invention;

FIGS. 6(a) and 6(b) are perspective views showing a method of manufacturing a semiconductor module in accordance with a second exemplary embodiment of the present invention;

FIGS. 7(a) and 7(b) are perspective views showing the method of manufacturing a semiconductor module in accordance with the second exemplary embodiment of the present invention;

FIG. 8 is a perspective view showing a method of manufacturing a semiconductor module in accordance with a third exemplary embodiment of the present invention;

FIGS. 9(a) and 9(b) are perspective views showing the method of manufacturing a semiconductor module in accordance with the third exemplary embodiment of the present invention;

FIGS. 10(a) and 10(b) are perspective views showing a method of manufacturing a semiconductor module in accordance with a fourth exemplary embodiment of the present invention;

FIGS. 11(a) and 11(b) are perspective views showing the method of manufacturing a semiconductor module in accordance with the fourth exemplary embodiment of the present invention;

FIGS. 12(a)-12(d) are cross-sectional views showing a method of manufacturing a semiconductor module in accordance with a fifth exemplary embodiment of the present invention;

FIGS. 13(a)-13(e) are cross-sectional views showing the method of manufacturing a semiconductor module in accordance with the fifth exemplary embodiment of the present invention;

FIGS. 14(a)-14(d) are cross-sectional views showing a related art method of manufacturing a semiconductor module; and

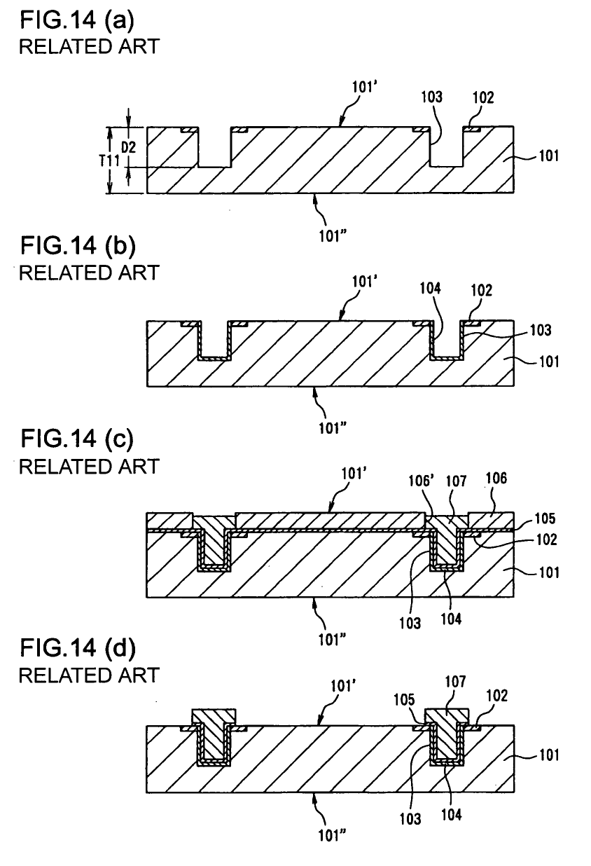

FIGS. 15(a)-15(d) are cross-sectional views showing the related art method of manufacturing a semiconductor module.

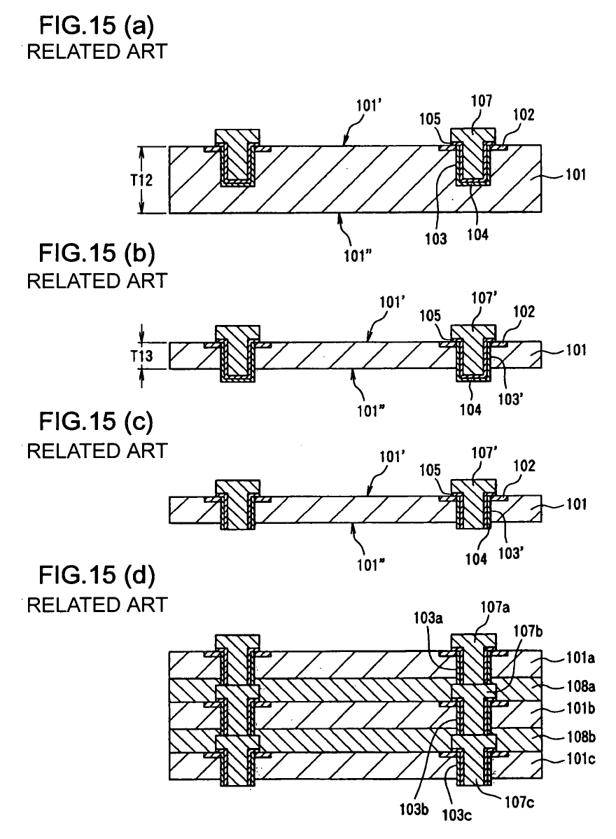

### DETAILED DESCRIPTION OF PREFERRED EMBODIMENTS

A method of manufacturing a semiconductor device and a method of manufacturing a semiconductor module in accordance with exemplary embodiments of the present invention are described below with reference to the accompanying drawings.

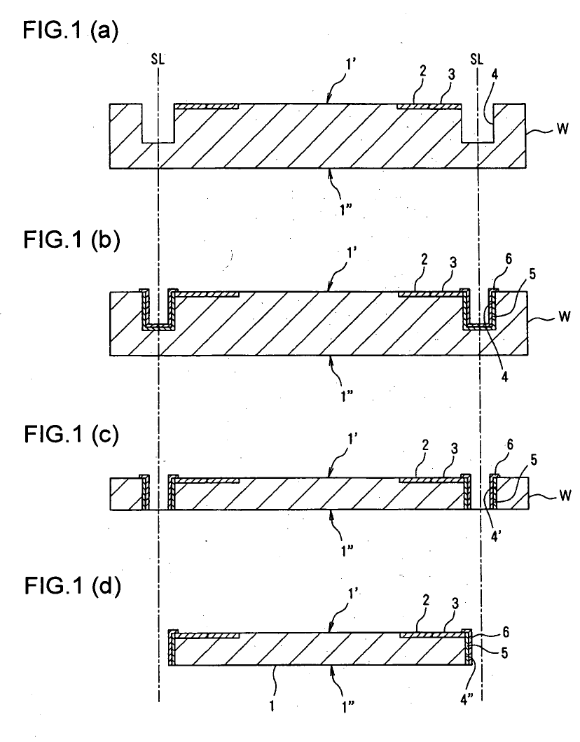

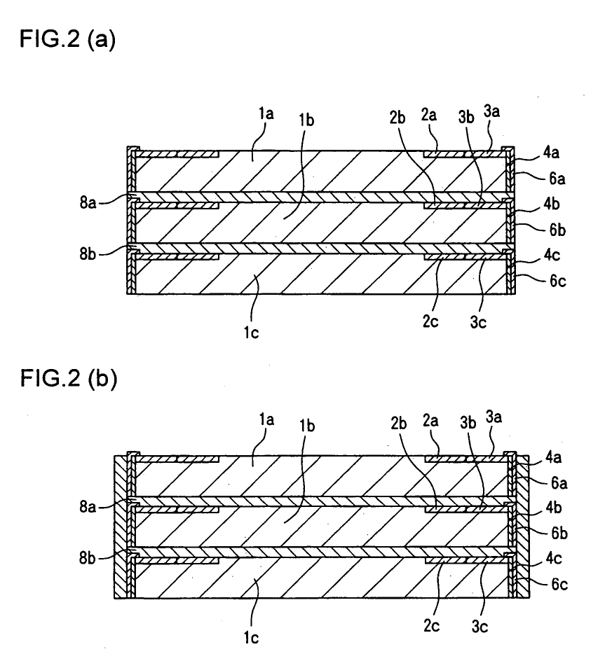

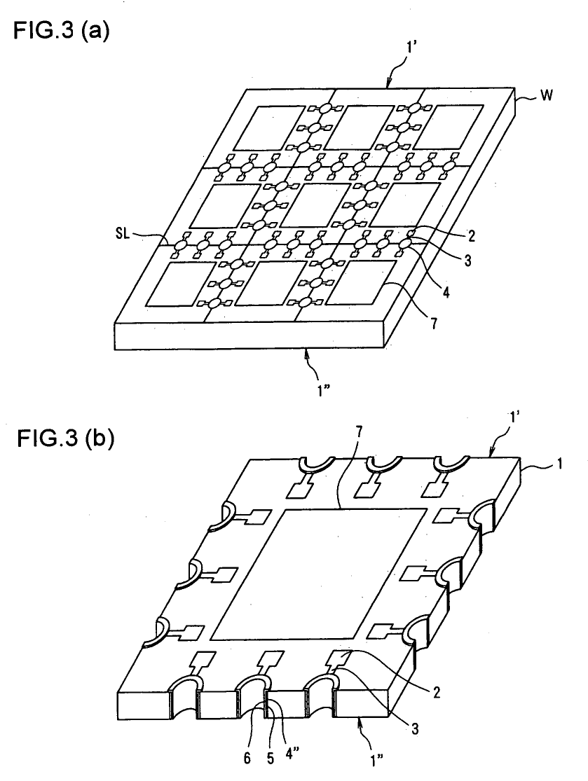

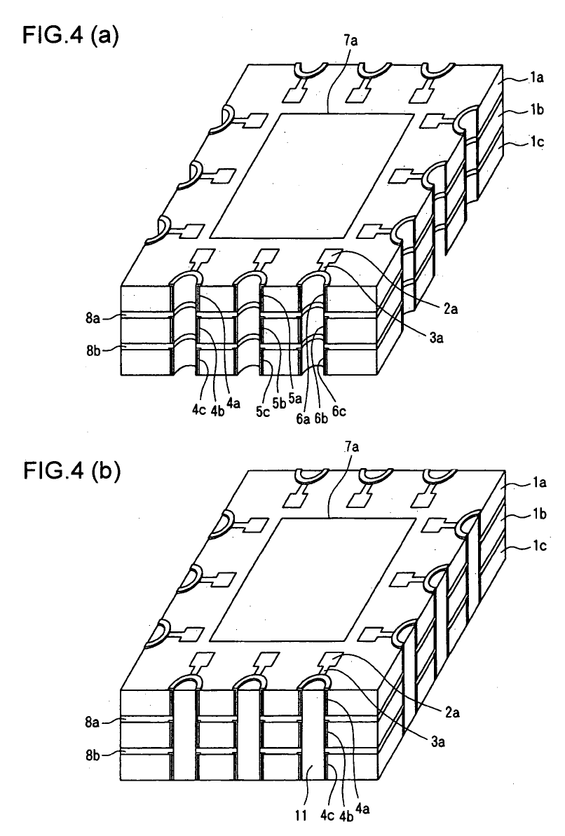

FIGS. 1(a)-2(b) are cross-sectional views showing a method of manufacturing a semiconductor device in accordance with a first exemplary embodiment of the present invention, and FIGS. 3(a)-4(b) are perspective views showing a method of manufacturing a semiconductor device in accordance with the first exemplary embodiment of the present invention.

Referring to FIG. 1(a) and FIG. 3(a), active regions 7 that are defined by scribe lines SL are formed on a semiconductor wafer W, pad electrodes 2 are formed on an active surface 1′ of the semiconductor wafer W, and the pad electrodes 2 are connected to wiring layers 3 that extend over the scribe lines SL.

Then, for example, by using photolithography technique and dry etching technique, trench sections 4 are formed at the scribe lines SL of the semiconductor wafer W.

Next, as indicated in FIG. 1(b), for example, a photolithography technique and a CVD technique are used to form dielectric films 5 within the trench sections 4. As the dielectric films 5, for example, silicon oxide films or silicon nitride films can be used.

Then, for example, by using photolithography technique and sputter technique, under barrier metal films 6 are formed within the trench sections 4 that are covered by the dielectric films 5, and the under barrier metal films 6 formed within the trench sections 4 are connected to the wiring layers 3. For the under barrier metal films 6, for example, TiW, TiN, Cr or Ni can be used.

Next, as indicated in FIG. 1(c), a back surface 1″ of the semiconductor wafer W is ground by using back grinding, thereby thinning down the semiconductor wafer W.

The back grinding of the back surface 1″ of the semiconductor wafer W is completed before the dielectric films 5 are exposed.

Then, when the semiconductor wafer W is thinned down by the back grinding, the back surface 1″ of the semiconductor wafer W is dry etched, to further thin down the semiconductor wafer W, to thereby remove the dielectric films 5 and the under barrier metal films 6 so that the trench sections 4 penetrate to form through holes 4′ in the semiconductor wafer W. As an etching gas used for the dry etching of the back surface 1″ of the semiconductor wafer W, for example, CL₂, HBr or SF₆ can be used, and as an etching gas used for the dry etching of the dielectric films 4, for example, CL₂, HBr or SF₆ can be used.

Next, as indicated in FIG. 1(d) and FIG. 3(b), the semiconductor wafer W having the through holes 4′ is cut along the scribe lines SL, to thereby divide the through holes 4′ in their longitudinal direction to form grooves 4″ in side walls of semiconductor substrates 1.

As shown in FIG. 2(a) and FIG. 4(a), semiconductor substrates 1a-1c having the grooves 4a-4c formed in their side walls are stacked in layers through resin layers 8a and 8b. When the semiconductor substrates 1a-1c and the resin layers 8a and 8b are stacked in layers, the grooves 4a-4c formed in the side walls of the semiconductor substrates 1a-1c are aligned with one another in the longitudinal direction.

As shown in FIG. 2(b) and FIG. 4(b), conductive material 11 is charged within the grooves 4a-4c to cross over the resin layers 8a and 8b, thereby providing interlayer connections among the pad electrodes 2a-2c formed in the semiconductor substrates 1a-1c, respectively.

As the conductive material 11 that is filled in the grooves 4a-4c, for example, Ag paste, solder paste, or conductive slurry can be used.

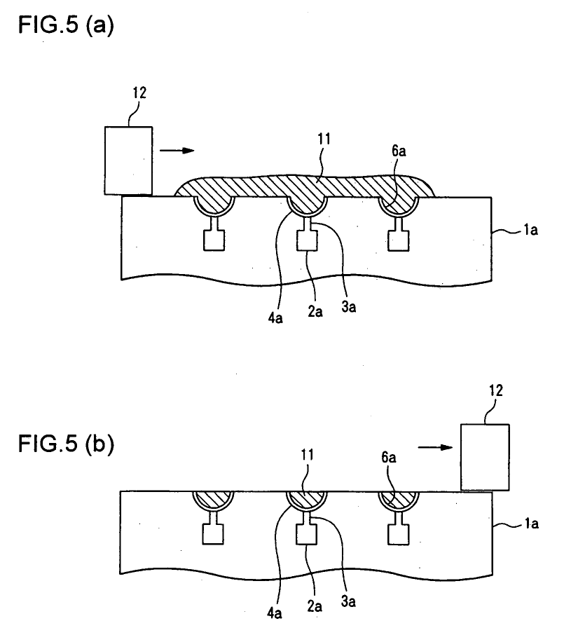

FIGS. 5(a) and 5(b) are side views indicating a method of filling conductive material in accordance with an exemplary embodiment of the present invention.

In FIG. 5(a), for filling the grooves 4a-4c with the conductive material 11, the conductive material 11 is coated on wall surfaces of the semiconductor substrates 1a-1c that are stacked in layers.

Then, a stage 12 is slid on the wall surfaces of the semiconductor substrates 1a-1c that are coated with the conductive material 11, to scrape off the conductive material 11 on the wall surfaces of the semiconductor substrates 1a-1c, thereby filling the conductive material 11 in the grooves 4a-4c.

Accordingly, by filling the conductive material 11 on the side walls of the semiconductor substrates 1a-1c, interlayer connections among the semiconductor substrates 1a-1c can be provided, and conductive layers for providing the interlayer connections can be formed after the semiconductor substrates 1a-1c are stacked in layers, and there is no need to provide through electrodes in the active surfaces of the semiconductor substrates 1a-1c.

Accordingly, while reducing or suppressing enlargement of the chip size, the width of the grooves 4a-4c can be readily expanded, and the alignment to be conducted when the semiconductor substrates 1a-1c are stacked in layers can be facilitated; interlayer connections among the semiconductor substrates 1a-1c can be provided without being affected by height variations of through electrodes and/or warps in the semiconductor substrates 1a-1c; and the reliability in interlayer connections can be enhanced while reducing the size of the stacked layered structure.

Also, by providing the interlayer connections through the side walls of the semiconductor substrates 1a-1c, the resin layers 8a and 8b can be coated all over the semiconductor substrates 1a-1c, without interfering with the interlayer connections.

Consequently, the semiconductor substrates 1a-1c can be insulated from one another without complicating the manufacturing process, and the sealing property of the semiconductor substrates 1a-1c can be readily enhanced, and thus the reliability of the semiconductor module can be enhanced.

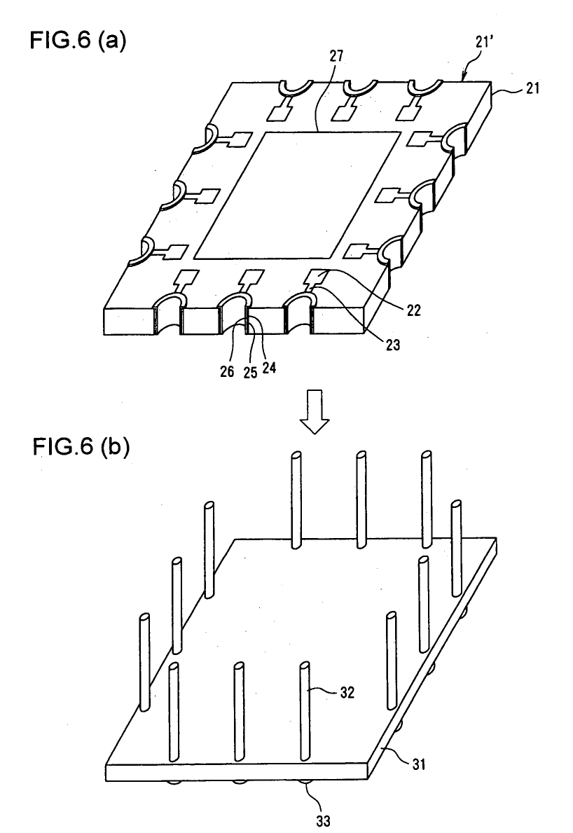

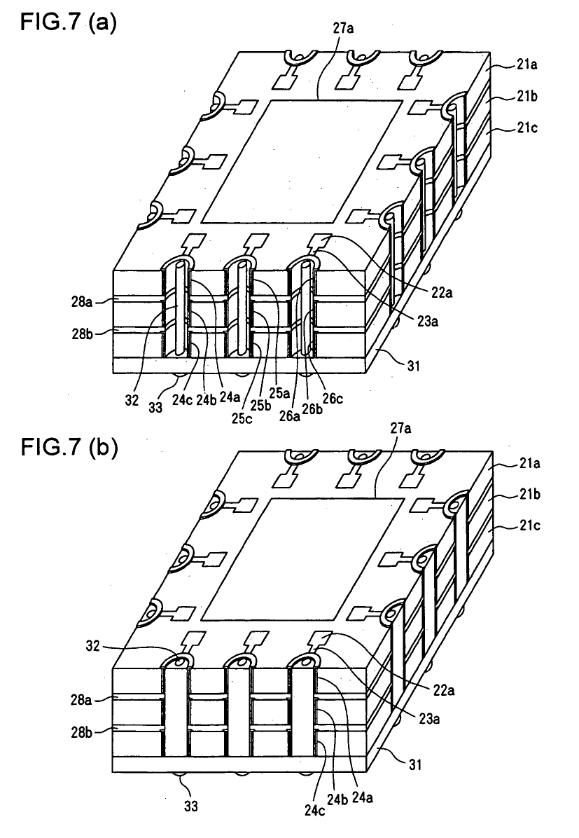

FIGS. 6(a)-7(b) are perspective views showing a method of manufacturing a semiconductor module in accordance with a second exemplary embodiment of the present invention.

Referring to FIG. 6(a), an active region 27 is formed on a semiconductor substrate 21, grooves 24 are formed in side walls of the semiconductor substrate 22, and pad electrodes 22 and wiring layers 23 are formed on an active surface 21′ of the semiconductor substrate 21. Also, the pad electrodes 22 are connected to the wiring layers 23 that extend to the grooves 24, surfaces of the grooves 24 are covered with dielectric films 25, and under barrier metal films 26 that are connected to the wiring layers 23 are formed within the grooves 24 that are covered with the dielectric films 25.

On the other hand, as indicated in FIG. 6(b), pin-like terminals 32 are erected on an interposer substrate 31 at positions corresponding to the grooves 24 of the semiconductor substrate 21, bump electrodes 33 are formed on a back surface of the interposer substrate 31, and the pin-like terminals 32 and the bump electrodes 33 are connected by internal wirings.

The pin-like terminals 32 can be composed of metal material having good solder-wettability such as Cu, or metal material that is solder plated on its surface, and the diameter of each pin-like terminal 32 can be set such that the pin-like terminals 32 can be stored in the grooves 24.

Then, for realizing a stacked layered structure with the semiconductor substrate 21, the semiconductor substrate 21 is stacked on the interposer substrate 31 along the pin-like terminals 32 in a manner that the pin-like terminals 32 are inserted in the grooves 24 of the semiconductor substrate 21.

As a result, as indicated in FIG. 7(a), a stacked layered structure of semiconductor substrates 21a-21c that are interlayer-insulated by resin layers 28a and 28b can be formed. Grooves 24a-24c are formed in the semiconductor substrates 21a-21c, respectively, surfaces of the grooves 24a-24c are covered with dielectric films 25a-25c, respectively, and under barrier metal films 26a-26c are formed within the grooves 24a-24c that are covered with the dielectric films 25a-25c, respectively. Then, for example, pad electrodes 22a that are formed on the semiconductor substrate 21a are connected to the under barrier metal films 26a via the wiring layers 23a.

Next, as indicated in FIG. 7(b), conductive material 34 is adhered along the pin-like terminals 32 by solder dipping, thereby filling the conductive material 34 in the grooves 24a-24c in a manner to extend across the resin layers 28a and 28b.

In this manner, by stacking the semiconductor substrates 21a-21c along the pin-like terminals 32, the semiconductor substrates 21a-21c can be stacked in layers while the grooves 24a-24c are aligned with one another. Accordingly, the time and labor for the positioning can be alleviated, and the stacked layered structure of the semiconductor substrates 21a-21c can be readily realized.

Also, by composing the pin-like terminals 32 with metal material having good solder-wettability, the conductive material 34 can be collectively filled in the grooves 24a-24c by solder dipping or the like.

Also, by composing the pin-like terminals 32 with solder-plated metal material, the grooves 24a-24c can be collectively connected by heat treatment with solder through the resin layers 28a and 28b.

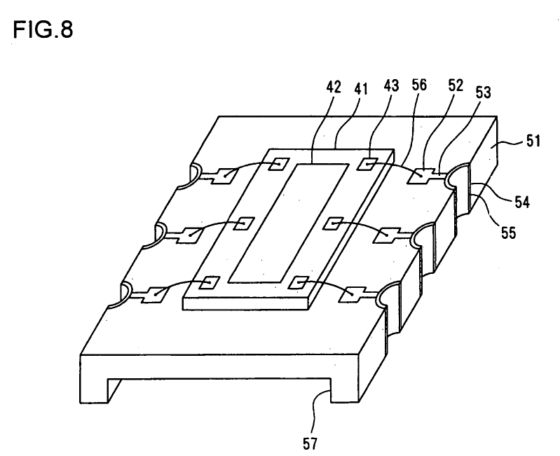

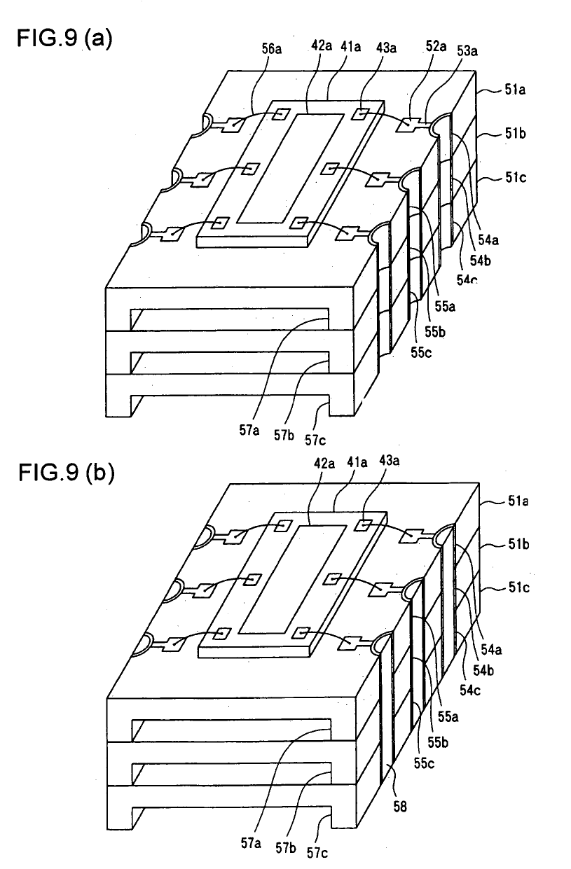

FIGS. 8-9(b) are perspective views showing a method of manufacturing a semiconductor module in accordance with a third exemplary embodiment of the present invention.

In FIG. 8, an active region 42 is formed on a semiconductor substrate 41, and pad electrodes 43 are formed on an active surface of the semiconductor substrate 41.

On the other hand, terminal electrodes 52 and wiring layers 53 are formed on an interposer substrate 51, grooves 54 are formed in side walls of the interposer substrate 51, and the terminal electrodes 52 are connected to the wiring layers 53 that extend to the grooves 54.

Also, under barrier metal films 55 that are connected to the wiring layers 53 are formed within the grooves 54 that are formed in the side walls of the interposer substrate 51, and a concave section 57 that is capable of storing the semiconductor substrates 41 is formed in a back surface of the interposer substrate 51.

As the interposer substrate 51, for example, a resin substrate, a ceramics substrate or a glass epoxy substrate can be used, and for the under barrier metal films 55, for example, TiW, TiN, Cr or Ni can be used.

Then, the semiconductor substrate 41 is mounted on the interposer substrate 51, the pad electrodes 43 on the semiconductor substrate 41 are connected to the terminal electrodes 52 on the interposer substrate 51 by wires 56.

As shown in FIG. 9(a), interposer substrates 51a-51c having semiconductor substrates respectively mounted thereon are stacked in layers, to thereby realize a three-dimensional structure of the semiconductor substrates.

By providing concave sections 57a-57c in back surfaces of the respective interposer substrates 51a-51c, semiconductor substrates that are respectively mounted on the interposer substrates 51a-51c can be stored in the concave sections 57a-57c in overlying layers of the interposer substrates 51a-51c, respectively, such that the interposer substrates 51a-51c having the semiconductor substrates respectively mounted thereon can be stacked in layers with good precision.

Grooves 54a-54c are formed in the side walls of the respective interposer substrates 51a-51c, the concave sections 57a-57c are formed in the back surfaces of the respective interposer substrates 51a-51c, and under barrier metal films 55a-55c are formed in the respective grooves 54a-54c.

Then, for example, terminal electrodes 52a and wiring layers 53a are formed on the interposer substrate 51a, the terminal electrodes 52a are connected to the under barrier metal films 55a via the wiring layers 53a, the semiconductor substrate 41a is mounted on the interposer substrate 51a, and pad electrodes 43a on the semiconductor substrate 41a are connected to the terminal electrodes 52a on the interposer substrate 51a by wires 56a.

As shown in FIG. 9(b), by filling conductive material 58 in the grooves 54a-54c that are formed in the side walls of the respective interposer substrates 51a-51c, interlayer connections among the semiconductor substrates are realized through the interposer substrates 51a-51c.

Accordingly, even when the types and/or chip sizes of the semiconductor substrates 51 are different from one another, a three-dimensional mounting of the semiconductor substrates 51 can be readily realized while reducing or suppressing enlargement of the chip size and enhancing the reliability in the interlayer connections.

Consequently, the electronic device can be made smaller in size and lighter, the reliability in the electronic device can be enhanced, and a variety of functions can be readily added to the electronic device.

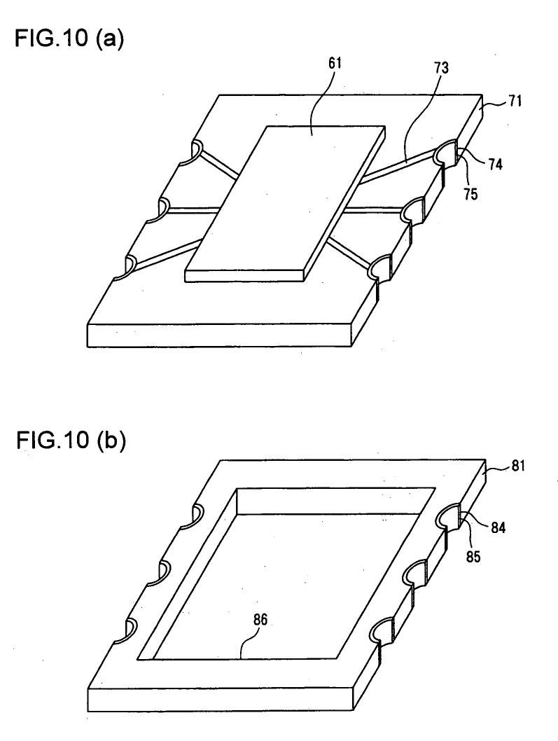

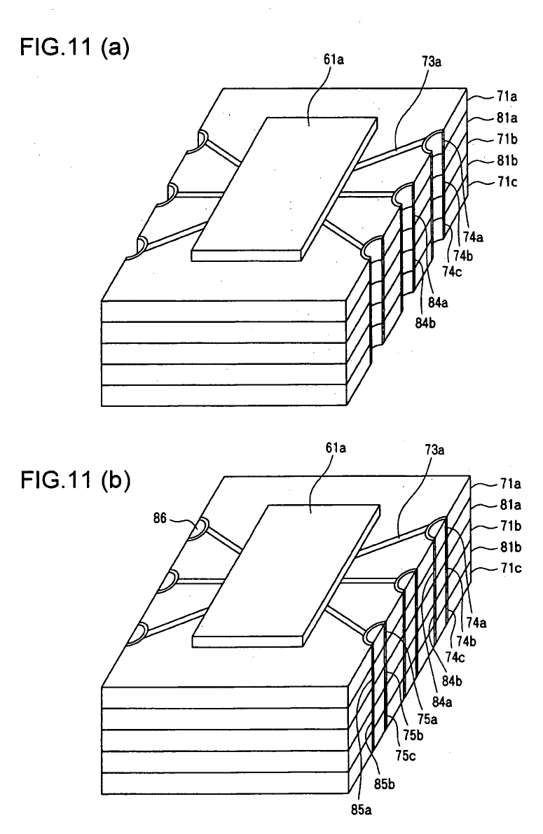

FIGS. 10(a)-11(b) are perspective views showing a method of manufacturing a semiconductor module in accordance with a fifth exemplary embodiment of the present invention.

In FIG. 10(a), wiring layers 73 are formed on an interposer substrate 71, grooves 74 are formed in side walls of the interposer substrate 71, and under barrier metal films 75 that are connected to the wiring layers 73 are formed in the grooves 74 that are formed in the side walls of the interposer substrate 71.

Further, a semiconductor substrates 61 is mounted on the interposer substrate 71 by a face down method, and pad electrodes of the semiconductor substrates 61 are connected to the under barrier metal films 75 by wiring layers 73.

On the other hand, in FIG. 10(b), an intermediate substrate 81 is provided with an opening section 86 that is capable of storing the semiconductor substrates 61, grooves 84 are formed in side walls of the intermediate substrate 81, and under barrier metal films 85 are formed in the grooves 84 formed in the side walls of the intermediate substrate 81.

As the interposer substrate 71 and the intermediate substrate 81, for example, resin substrates, ceramics substrates or glass epoxy substrates can be used, and for the under barrier metal films 75 and 85, for example, TiW, TiN, Cr or Ni can be used.

Then, as indicated in FIG. 11(a), by stacking interposer substrates 71a-71c having semiconductor substrates respectively mounted thereon in layers with the intermediate substrates 81a and 81b being sandwiched between them, a three-dimensional mounting structure of the semiconductor substrates can be realized.

By sandwiching the intermediate substrates 81a and 81b among the interposer substrates 71a-71c, the semiconductor substrates that are mounted on the respective interposer substrates 71a-71c can be stored in the opening sections of the intermediate substrates 81a and 81b, respectively, such that the interposer substrates 71a-71c having the semiconductor substrates respectively mounted thereon can be stacked in layers with good precision.

Further, by also providing grooves 84a and 84b in side walls of the intermediate substrates 81a and 81b, interlayer connections can be readily provided via the side walls of the interposer substrates 71a-71c even when the intermediate substrates 81a and 81b are sandwiched between the interposer substrates 71a-71c.

Grooves 74a-74c are formed in side walls of the respective interposer substrates 71a-71c, and under barrier metal films 75a-75c are formed in the respective grooves 74a-74c.

Also, the grooves 84a and 84c are formed on the side walls of the respective intermediate substrates 81a and 81b, and under barrier metal films 85a and 85b are formed in the grooves 84a and 84b, respectively.

Then, for example, on the interposer substrate 71a, wiring layers 73a that are connected to the under barrier metal films 75a are formed, and the semiconductor substrate 61a that is connected to the wiring layers 73a is mounted by a face down method.

As shown in FIG. 11(b), by filling conductive material 86 in the grooves 74a-74c and 84a-84c formed in the side walls of the interposer substrates 71a-71c and the intermediate substrates 81a and 81b, respectively, interlayer connections among the semiconductor substrates are realized via the interposer substrates 71a-71c and the intermediate substrates 81a and 81b.

Consequently, even when the types and/or chip sizes of the semiconductor substrates 71 are different from one another, a three-dimensional mounting of the semiconductor substrates 71 can be readily realized while reducing or suppressing enlargement of the chip size, and the reliability in the interlayer connections can be enhanced while reducing or preventing complication of the interposer substrates 71a-71c.

Accordingly, the electronic device can be made smaller in size and lighter, the reliability in the electronic device can be enhanced, and a variety of functions can be readily added to the electronic device while reducing or suppressing cost increases.

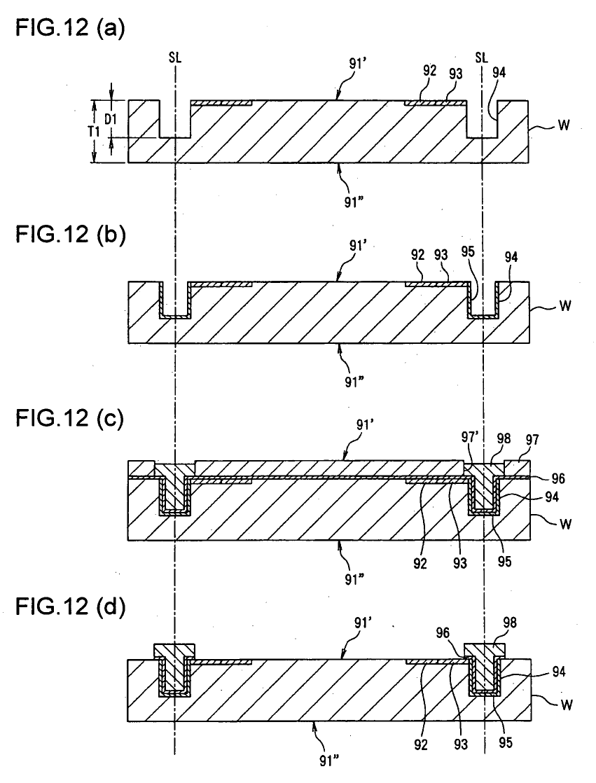

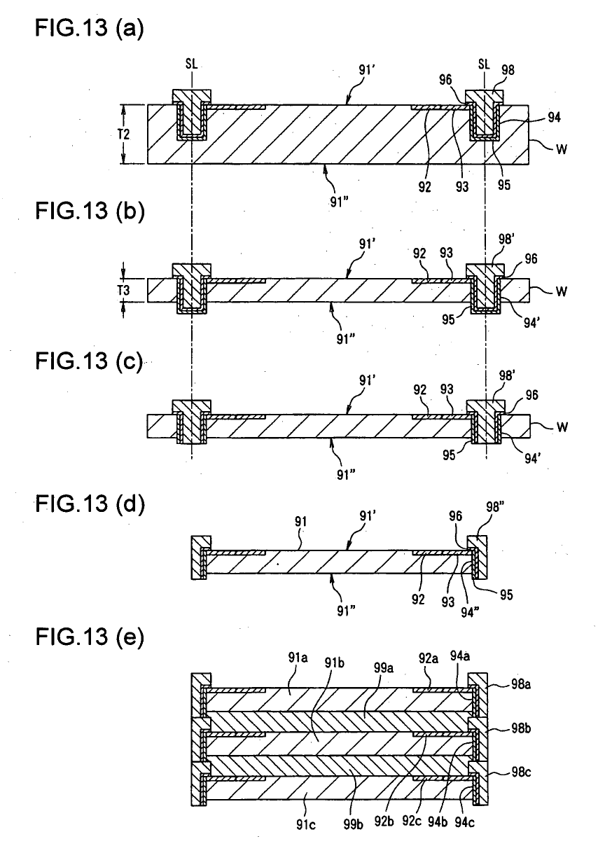

FIGS. 12(a)-13(e) are cross-sectional views showing a method of manufacturing a semiconductor module in accordance with a fifth exemplary embodiment of the present invention.

Referring to FIG. 12(a), active regions that are defined by scribe lines SL are formed on a semiconductor wafer W, pad electrodes 92 are formed on an active surface 91′ of the semiconductor wafer W, and the pad electrodes 92 are connected to wiring layers 93 that extend over the scribe lines SL.

For example, by using photolithography technique and dry etching technique, trench sections 94 are formed at the scribe lines SL of the semiconductor wafer W.

The thickness T1 of the semiconductor wafer W can be 625 μm when a 6-inch wafer is used, and 725 μm when an 8-inch wafer is used. The depth D1 of the trench section 94 can be, for example, 70 μm.

Next, as indicated in FIG. 12(b), for example, photolithography technique and CVD technique are used to form dielectric films 95 on bottom surfaces and side surfaces inside the trench sections 94. As the dielectric films 95, for example, silicon oxide films or silicon nitride films can be used.

Next, as indicated in FIG. 12(c), for example, by sputtering or vapor deposition, seed electrodes 96 are formed on the semiconductor substrates 91 including the inside of the trench sections 94. For the seed electrodes 96, conductive material, such as, for example, nickel (Ni), copper (Cu), gold (Au), titanium (Ti) or tungsten (W) can be used.

Then, a plating resist layer 97 having opening sections 97′ provided at positions corresponding to the trench sections 94 are formed on the semiconductor substrate 91 having the seed electrodes 96 formed thereon. The size of the opening sections 97′ is set such that the opening sections 97′ extend over the wiring layers 93.

Then, by conducing electrolytic plating using the seed electrodes 96 as plating terminals, embedded electrodes 98 are formed through the opening sections 97′ provided in the plating resist layer 97 in the trench sections 94 and the opening sections 97′.

As the embedded electrodes 98, for example, a one-layer structure composed of nickel (Ni), copper (Cu) or gold (Au), or a two-layer structure having metal, such as nickel (Ni), copper (Cu) or gold (Au) and solder material, such as Sn, Sn—Pb, Sn—Ag, Sn—Cu, Sn-Zu or the like stacked thereon may be used.

Also, the embedded electrodes 98 may be formed by using an electroless plating method, besides the electrolytic plating method; and also, conductive slurry or conductive paste can be injected in the trench sections 94 by an ink jet method.

Next, as indicated in FIG. 12(d), the plating resist layer 97 is removed, and the seed electrodes 96 are etched by using the embedded electrodes 98, thereby exposing the active surface 91′ of the semiconductor wafer W.

Next, as indicated in FIG. 13(a), a back surface 91″ of the semiconductor wafer W is ground by using back grinding, thereby thinning down the semiconductor wafer W.

The back grinding of the back surface 91″ of the semiconductor wafer W is completed before the dielectric films 95 are exposed, such that the thickness T2 of the semiconductor wafer W after the grinding can be, for example, 100 μm.

Then, as indicated in FIG. 13(b), the back surface 91″ of the semiconductor wafer W is dry etched, to further thin down the semiconductor wafer W, such that the trench sections 93 penetrate to form through holes 94′ in the semiconductor wafer W, and tips of the embedded electrodes 98 covered with the dielectric films 95 are exposed to form through electrodes 98′. The thickness T3 of the semiconductor wafer W after the dry etching can be, for example, 50 μm. Also, as an etching gas used for the dry etching of the back surface 91″ of the semiconductor wafer W, for example, CL₂, HBr or SF₆ can be used.

Next, as indicated in FIG. 13(c), the dielectric films 95 at the tips of the through electrodes 98′ are dry etched, to thereby remove the dielectric films 95 at the tips of the through electrodes 98′. As an etching gas used for the dry etching of the dielectric films 95 at the tips of the through electrodes 98′, for example, CL₂, HBr or SF₆ can be used.

As shown in FIG. 13(d), the semiconductor wafer W having the through electrodes 98′ formed therein is cut along the scribe lines SL to divide the through electrodes 98′ in their longitudinal direction, thereby forming grooves 94″ in side walls of semiconductor substrates 91, and embedded electrodes 98″ embedded in the grooves 94″.

As shown in FIG. 13(e), the semiconductor substrates 91a-91c are stacked in layers in a manner that the embedded electrodes 98a-98c filled in the grooves 94a-94c of the respective semiconductor substrates 91a-91c are in contact with one another; and resin 99a and 99b is injected in gaps between the semiconductor substrates 91a-91c to thereby form a stacked layered structure of the semiconductor substrates 91a-91c.

Accordingly, by cutting the semiconductor wafer W along the scribe lines SL, the embedded electrodes 98″ can be collectively formed on the side walls of the semiconductor substrates 91.

For this reason, there is no need to fill conductive material in the grooves 94″ that would otherwise be formed after cutting the semiconductor wafer W, which can simplify the manufacturing process. Further, the embedded electrodes 98″ can be formed on the side walls of the semiconductor substrate 91 with good precision, such that interlayer connections using the side walls of the semiconductor substrate 91 can be stably provided.

In the exemplary embodiments described above, interlayer connections are provided through side walls of semiconductor chips. However, the present invention is not limited to semiconductor chips, but may also be applicable to, for example, a method for providing interlayer connections through side walls of glass substrates or sapphire substrates having thin film transistors or the like formed thereon.

Also, the bump electrode structure described above is applicable to electronic devices, such as, for example, liquid crystal display devices, portable telephones, portable information terminals, video cameras, digital cameras and MD (Mini Disc) players, and can make electronic devices smaller and lighter without deteriorating the reliability of the electronic devices.

As described above, according to the present invention, interlayer connections are provided through side walls of semiconductor chips. Accordingly, interlayer connections of the semiconductor chips can be provided without providing through electrodes in active regions, conductive layers in upper and lower layers can be readily aligned, and the influence of height variations of the conductive layers and/or warps in the semiconductor chips is reduced eliminated, such that the reliability in the interlayer connections can be enhanced.

What is claimed is:

1. A semiconductor device characterized in comprising:
a wiring layer formed on a main surface of a semiconductor chip; and
a conductive layer for interlayer connections that is connected to the wiring layer and formed in a side wall of the semiconductor chip.

2. A semiconductor device characterized in comprising:
electrode pads formed on a main surface of a semiconductor chip;
grooves formed in a section of the semiconductor chip that traverses in a thickness direction of the semiconductor chip;
conductive layers filled in the grooves; and
wiring layers that connect the electrode pads and the conductive layers.

3. A semiconductor module characterized in comprising:
semiconductor chips stacked in layers;
conductive layers that are formed in side walls of the respective semiconductor chips for providing interlayer connections among the semiconductor chips; and
wiring layers that are formed on main surfaces of the respective semiconductor chips and connected to the conductive layers.

4. A semiconductor module characterized in comprising:
semiconductor chips stacked in layers;
electrode pads formed on main surfaces of the respective semiconductor chips;
grooves that are formed in sections of the respective semiconductor chips that traverse in a thickness direction of the semiconductor chips;
conductive layers filled in the grooves for providing interlayer connections among the semiconductor chips; and
wiring layers that connect the electrode pads and the conductive layers, respectively.

5. A semiconductor module characterized in comprising:
semiconductor chips stacked in layers;
electrode pads formed on main surfaces of the respective semiconductor chips;
grooves that are formed in sections of the respective semiconductor chips that traverse in a thickness direction of the semiconductor chips;
wiring layers that connect the electrode pads and the conductive layers;
pin-like terminals that are embedded in the grooves and disposed in a stacking direction of the semiconductor chips;
an interposer substrate with the pin-like terminals standing thereon; and
conductive layers filled in the grooves with the pin-like terminals therein.

6. A semiconductor module according to claim 3, characterized in that the semiconductor chips are stacked in layers through dielectric resin.

7. A semiconductor module characterized in comprising:
an interposer substrate having a wiring layer formed on a main surface thereof;
a semiconductor chip that is connected to the wiring layer and mounted on the interposer substrate;
grooves formed in a side wall of the interposer substrate that traverses in a thickness direction of the interposer substrate; and
conductive layers filled in the grooves.

8. A semiconductor module characterized in comprising:
interposer substrates stacked in layers;
wiring layers formed on main surfaces of the interposer substrates;
semiconductor chips that are connected to the wiring layers and mounted on the interposer substrates;
grooves formed in side walls of the interposer substrates that traverse in a thickness direction of the interposer substrates;
conductive layers filled in the grooves for providing interlayer connections among the interposer substrates; and
recessed sections formed in back surfaces of the interposer substrates for storing the semiconductor chips.

9. A semiconductor module characterized in comprising:
an intermediate substrate having an opening section formed therein;
interposer substrates stacked in layers through the intermediate substrate;
wiring layers formed on main surfaces of the interposer substrates;
semiconductor chips that are connected to the wiring layers and mounted on the interposer substrates;
first grooves formed in side walls of the interposer substrates that traverse in a thickness direction of the interposer substrates;
second grooves formed in a side wall of the intermediate substrate that traverses in a thickness direction of the intermediate substrate; and
conductive layers filled in the first grooves and the second grooves for providing interlayer connections among the interposer substrates through the intermediate substrate.

10. An electronic device characterized in comprising:
semiconductor chips stacked in layers;
electrode pads formed on main surfaces of the respective semiconductor chips;
grooves that are formed in sections of the respective semiconductor chips that traverse in a thickness direction of the semiconductor chips;
conductive layers filled in the grooves for providing interlayer connections among the semiconductor chips;
wiring layers that connect the electrode pads and the conductive layers, respectively; and
an electronic component that is connected to the semiconductor chips through the conductive layers.

11. An electronic device characterized in comprising:
semiconductor chips stacked in layers;
electrode pads formed on main surfaces of the respective semiconductor chips;
grooves that are formed in sections of the respective semiconductor chips that traverse in a thickness direction of the semiconductor chips;
wiring layers that connect the electrode pads and the conductive layers, respectively;
pin-like terminals that are inserted in the grooves and disposed in a stacking direction of the semiconductor chips;
an interposer substrate with the pin-like terminals standing thereon;
conductive layers filled in the grooves with the pin-like terminals therein; and
an electronic component that is connected to the semiconductor chips through the conductive layers.

12. An electronic device characterized in comprising:
interposer substrates stacked in layers;
wiring layers formed on main surfaces of the interposer substrates;
semiconductor chips that are connected to the wiring layers and mounted on the interposer substrates;
grooves formed in side walls of the interposer substrates that traverse in a thickness direction of the interposer substrates;
conductive layers filled in the grooves for providing interlayer connections among the interposer substrates;
recessed sections formed in back surfaces of the interposer substrates for storing the semiconductor chips; and
an electronic component that is connected to the semiconductor chips through the conductive layers.

13. An electronic device characterized in comprising:
an intermediate substrate having an opening section formed therein;
interposer substrates stacked in layers through the intermediate substrate;
wiring layers formed on main surfaces of the interposer substrates;
semiconductor chips that are connected to the wiring layers and mounted on the interposer substrates;
first grooves formed in side walls of the interposer substrates that traverse in a thickness direction of the interposer substrates;
second grooves formed in a side wall of the intermediate substrate that traverses in a thickness direction of the intermediate substrate;
conductive layers filled in the first grooves and the second grooves for providing interlayer connections among the interposer substrates through the intermediate substrate; and
an electronic component that is connected to the semiconductor chips through the conductive layers.

14. A method for manufacturing a semiconductor device, characterized in comprising:
a step of forming through holes on cutting lines of a semiconductor wafer;
a step of cutting the semiconductor wafer along the cutting lines into chips; and
a step of filling conductive layers in the through holes divided by the cutting step.

15. A method for manufacturing a semiconductor device, characterized in comprising:
a step of forming trench sections on cutting lines of a semiconductor wafer having wiring layers formed thereon;
a step of forming dielectric films within the trench sections;
a step of forming an under barrier metal layer that covers the dielectric films and is connected to the wiring layers;
a step of thinning a back surface of the semiconductor wafer to thereby make the trench sections penetrate to form through holes along the cutting lines;
a step of cutting the semiconductor wafer along the cutting lines into chips; and
a step of filling conductive layers in the through holes that are divided by the cutting step.

16. A method for manufacturing a semiconductor module, characterized in comprising:
a step of forming conductive layers on side walls of a semiconductor chip; and
a step of providing interlayer connections through the conductive layers formed on the side walls of the semiconductor chip.

17. A method for manufacturing a semiconductor module, characterized in comprising:
a step of forming through holes on cutting lines of a semiconductor wafer;
a step of cutting the semiconductor wafer along the cutting lines into chips;
a step of stacking the semiconductor chips formed by the cutting step; and
a step of filling conductive layers in the through holes cut by the cutting step.

18. A method for manufacturing a semiconductor module, characterized in comprising:
a step of forming through electrodes on cutting lines of a semiconductor wafer;
a step of cutting the semiconductor wafer along the cutting lines into chips; and
a step of providing interlayer connections among the semiconductor chips formed by the cutting step via the through electrodes that are cut by the cutting step.

19. A method for manufacturing a semiconductor module, characterized in comprising:
a step of forming trench sections on cutting lines of a semiconductor wafer having wiring layers formed thereon;
a step of forming dielectric films within the trench sections;
a step of forming an under barrier metal layer that covers the dielectric films and is connected to the wiring layers;
a step of thinning a back surface of the semiconductor wafer to thereby make the trench sections penetrate to form through holes along the cutting lines;
a step of cutting the semiconductor wafer along the cutting lines into chips;
a step of stacking the semiconductor chips formed by the cutting step; and
a step of filling conductive layers in the through holes that are divided by the cutting step.

20. A method for manufacturing a semiconductor module, characterized in comprising:
a step of forming through holes on cutting lines of a semiconductor wafer;
a step of cutting the semiconductor wafer along the cutting lines into chips;
a step of stacking the semiconductor chips on a interposer substrate having pin-like terminals standing thereon in a manner that the pin-like terminals are inserted in the through holes divided by the cutting step; and
a step of filling conductive layers in the through holes that are cut.

21. A method for manufacturing a semiconductor module, characterized in comprising:
a step of mounting semiconductor chips on interposer substrates having grooves formed in side walls thereof and recessed sections formed in back surfaces thereof;
a step of stacking the interposer substrates having the semiconductor chips mounted thereon in layers such that each of the semiconductor chips is stored in each of the recessed sections of an upper layer of the stacked interposer substrates; and
a step of filling conductive layers in the grooves of the interposer substrates to provide interlayer connections.

22. A method for manufacturing a semiconductor module, characterized in comprising:
a step of mounting semiconductor chips on interposer substrates having grooves formed in side surfaces thereof;
a step of stacking the interposer substrates having the semiconductor chips mounted thereon through intermediate substrates having opening sections formed in main surfaces thereof and grooves formed in side walls thereof; and
a step of filling conductive layers in the grooves of the interposer substrates and the intermediate substrates to provide interlayer connections.
